(19) United States
(12) Patent Application Publication
(10) Pub. No.: US 2022/0245315 A1
(43) Pub. Date: Aug. 4, 2022

(54) DYNAMIC FPGA LOGIC CAPACITY BASED ON ACCURATE EARLY ROUTABILITY ESTIMATION

(71) Applicant: EFINIX, INC., Santa Clara, CA (US)

(72) Inventors: Marcel Gort, Toronto (CA); Nima Karimpour-Darav, Toronto (CA)

(21) Appl. No.: 17/546,858

(22) Filed: Dec. 9, 2021

Related U.S. Application Data
(60) Provisional application No. 63/144,877, filed on Feb. 2, 2021.

(51) Int. Cl. G06F 30/331; G06F 30/327; G06F 30/394

(52) U.S. Cl. CPC G06F 30/331; G06F 30/394; G06F 30/327

(57) ABSTRACT

A computer aided design (CAD) system receives a high level coding of a design for a circuit to be implemented in a field programmable gate array (FPGA). The system performs synthesis on the design, to produce a synthesized design. The system generates a routability estimation and a logic usage estimation for the synthesized design. The system determines whether the synthesized design is implementable on a specific FPGA, based on the routability estimation, the logic usage estimation, and available resources of the specific FPGA.

### RELATED APPLICATION

The present application claims the benefit under 35 USC 119(e) of U.S. Provisional Patent Application No. 63/144,877 filed Feb. 2, 2021, entitled “DYNAMIC FPGA LOGIC CAPACITY BASED ON ACCURATE EARLY ROUTABILITY ESTIMATION” and which is incorporated by reference in their entirety.

### BACKGROUND

When using most field programmable gate arrays (FPGAs), a designer is presented with a logic capacity for that FPGA. The FPGA contains some fixed number of logic block resources, and a designer is presented with that number. In reality, most of the area of an FPGA is devoted to multiplexors (muxes) for the programmable routing resources to connect logic blocks to each other, and in fact not to the logic blocks themselves. FPGA architects must decide up-front how much routing flexibility (muxing) to add. If they add too little routing flexibility, then FPGA users may not be able to use all the logic blocks that they have been promised. If architects add too much routing flexibility, then the FPGA area grows needlessly.

### BRIEF SUMMARY

Various embodiments of a computer aided design (CAD) system, a CAD tool, and a method for computer aided design of a circuit to be implemented in a field programmable gate array (FPGA) are presented herein. Embodiments relate to synthesis and analysis of a design for a circuit, in the context of implementing the design on an FPGA.

One embodiment is a method that is performed by a CAD system. The method includes receiving a high level coding of a design for a circuit to be implemented in a field programmable gate array (FPGA). The method includes performing synthesis on the design, to produce a synthesized design. The method includes generating a routability estimation and a logic usage estimation for the synthesized design. The method includes determining whether the synthesized design is implementable on a specific FPGA, based on the routability estimation, the logic usage estimation, and available resources of the specific FPGA.

One embodiment is a tangible, non-transitory, computer-readable media having instructions thereupon which, when executed by a processor, cause the processor to perform a method. The method embodied in the computer-readable media includes receiving a high level coding of a design for a circuit to be implemented in a field programmable gate array (FPGA). The method includes performing synthesis on the design, to produce a synthesized design. The method includes generating a routability estimation and a logic usage estimation for the synthesized design. The method includes determining and indicating to a user whether the synthesized design is implementable on a specific FPGA, based on the routability estimation, the logic usage estimation, and available resources of the specific FPGA.

One embodiment is a computer aided design (CAD) system. The CAD system includes a memory, to receive a high level coding of a design for a circuit to be implemented in a field programmable gate array (FPGA). The CAD system includes a processor. The processor is to perform synthesis on the design, to produce a synthesized design. The processor is to generate a routability estimation and a logic usage estimation for the synthesized design. The processor is to determine whether the synthesized design is implementable on a specific FPGA, based on the routability estimation, the logic usage estimation, and available resources of the specific FPGA.

### BRIEF DESCRIPTION OF THE DRAWINGS

Embodiments described herein will be understood more fully from the detailed description given below and from the accompanying drawings of various embodiments of the invention, which, however, should not be taken to limit the invention to the specific embodiments, but are for explanation and understanding only.

FIG. 1 shows how early routability estimation fits in to the overall FPGA CAD flow.

FIG. 2 shows a CAD system generating a routability estimation, a logic usage estimation, and an implementability determination for a design for a circuit, in an embodiment.

FIG. 3 shows an embodiment of available resources of an FPGA in an embodiment.

FIG. 4 shows aspects of a CAD tool in an embodiment.

FIG. 5 shows bipartitioning, with recursion, as a featured capability of a CAD tool in an embodiment.

FIG. 6 is a flow diagram of a method that is practiced by a CAD system, in an embodiment.

### DETAILED DESCRIPTION

In the following description, numerous details are set forth to provide a more thorough explanation of the present invention. It will be apparent, however, to one skilled in the art, that the present invention may be practiced without these specific details. In other instances, well-known structures and devices are shown in block diagram form, rather than in detail, in order to avoid obscuring the present embodiments.

CAD tools and CAD systems described herein present technological solutions to various technological problems. One problem addressed is how to decrease wasted computing time and resources that are spent attempting to implement a design for a circuit in an FPGA, only to find during or at the end of placement and routing (i.e., after both logic synthesis and physical synthesis) that the design does not fit in the available resources of the specific FPGA that was intended for the design implementation. Technological solutions described herein reduce such wasted computing time and resources, by providing earlier, more timely information about design implementation and relative fit to available resources of an FPGA, and thereby increase computing efficiency of CAD tools and CAD systems. One problem addressed is how to more efficiently use available resources of an FPGA. Technological solutions described herein provide information to system and user about use of available resources of an FPGA relative to a design implementation, and thereby support more efficient use of available resources of the FPGA.

One embodiment is a method of offering a logic capacity to an FPGA user that can dynamically change based on design properties determined after synthesis. The method includes presenting an FPGA logic capacity range to a user, and generating an early routing estimation related to a synthesized user design based on the properties of their netlist, where the routing estimation gives a user access to a different amount of logic. This embodiment and further aspects and embodiments are described below, with various features and tool capabilities that can be in various combinations in various further embodiments including computer aided design (CAD) systems, methods practiced by CAD systems, and tangible, computer-readable media that has instructions for a processor to practice a method.

Embodiments described herein include a technique that allows FPGA architects to devote less area to FPGA routing, while still allowing FPGA users to use all of the logic capacity that they have been promised. In one embodiment, users are initially presented a range of logic capacities of an FPGA. In one embodiment, this represents the minimum and maximum number of logic blocks that they can expect to fit on to an FPGA. The actual logic capacity that is offered to a user is determined based on the synthesized design.

In one embodiment, an equation based on pin density, a Rent parameter, and logic density (e.g., an equation quantifying Rent's rule) is used to calculate how many logic blocks can fit on to the FPGA. For easy-to-route designs, the user will be presented with the maximum number of logic blocks from the range. For hard-to-route designs, the user will be presented with the minimum number of logic blocks from the range.

If a user's design exceeds the dynamically determined logic capacity, they can either reduce the amount of logic in their design to reduce the logic used or reduce the connectivity between logic blocks, which has the effect of reducing the value of the Rent parameter, and will increase the logic capacity of the device. In terms of an equation based on Rent's rule that is used in various embodiments to determine routability, pin density itself may not affect Rent's parameter. There could be two circuits with identical numbers of logic blocks and Rent parameter, but one has higher pin density than the other. For example, a design of logic blocks that only connect to nearest neighbors will have a Rent parameter around 0.5, regardless of the number of connections to the nearest neighbor. This and further considerations can be accounted for in various embodiments through the use of additional parameters, for example a Rent's parameter scaling value based on pin density and nearest neighbor connections versus external block connections of a block, or a readily developed equation that recognizes the difference between nearest neighbor connections and connections to external blocks, and applies Rent's rule and a Rent parameter accordingly.

In some embodiments, users can also change compilation synthesis settings to target lower area and better routability. Alternatively, physical synthesis techniques can be used to automatically target lower area and better routability when a design exceeds the dynamic logic capacity.

The benefits of these various approaches (in various combinations in various embodiments) are that FPGA users can now use more of the FPGA resources, and FPGAs can be architected to have a higher number of logic blocks. These extra logic blocks can be used as logic blocks for netlists that are easy to route. Additionally, for Efinix FPGAs based on the exchangeable logic and routing (XLR) tile, e.g., Quantum™ architecture FPGAs, the extra logic blocks can be re-purposed as routing for harder to route netlists.

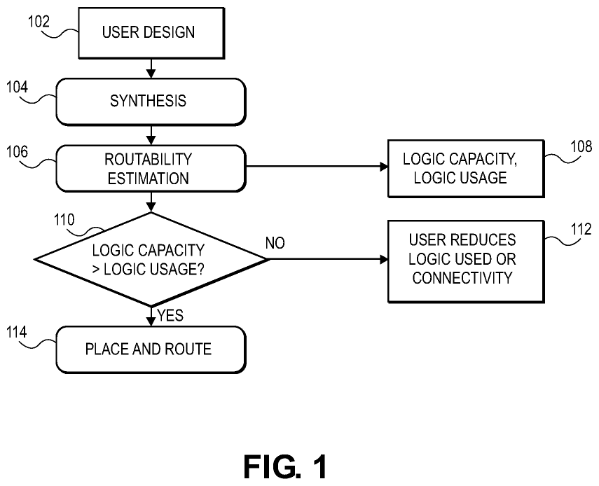

FIG. 1 is a flow diagram of one embodiment of a process for using routability estimates. The process is performed by processing logic that comprises hardware (e.g., circuitry, dedicated logic, etc.), software (e.g., software running on a chip, software run on a general-purpose computer system or a dedicated machine, etc.), firmware, or a combination of the three.

Referring to FIG. 1, the process begins with performing synthesis 104 on a user design 102. After synthesis 104, processing logic generates a routability estimation 106 for the synthesized design. Processing logic also presents a user with a logic capacity and logic usage 108.

Processing logic determines whether the logic capacity is greater than the logic usage associated with the synthesized design, in a determination action 110. If so, the process proceeds to place & route 114. If the logic usage is greater than the dynamically generated logic capacity, the user will not be allowed to continue to place & route. In that case, the tool has predicted that there is not enough logic and routing to satisfy the user design and user is prevented from going through the whole CAD flow. If such is the case, the user needs to reduce the logic used and/or the connectivity, in an action 112. In other words, the user will then need to rework their design to reduce wiring or logic. Alternatively, in one embodiment, the processing logic provides a synthesis option to target area/congestion. In another alternative, part of a physical synthesis flow automatically targets area/congestion if the design is too large. For example, there could be area thresholds, congestion thresholds, etc., that are system set or user settable. The system could alert a user, for example through a user interface, if congestion exceeds a threshold.

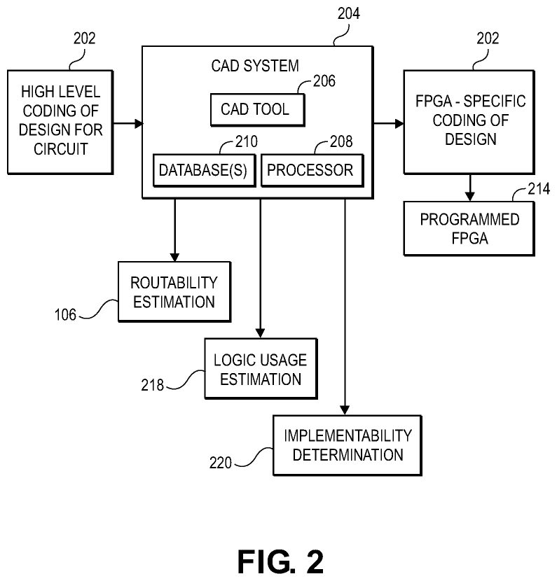

FIG. 2 shows a CAD system 204 generating a routability estimation 106, a logic usage estimation 218, and an implementability determination 220 for a design for a circuit, in an embodiment. The CAD system has a processor 208 that executes software and/or firmware, a memory for one or more databases 210 and other system usage, and a CAD tool 206 that performs various processes and has various features in various combinations as described herein. High level coding 202 of a design for a circuit to be implemented in an FPGA is input to the CAD system 204, for example by a user, through a user interface. For example, the high level coding 202 could be in the form of a file that has a design coded in RTL (register transfer language), Verilog or VHDL (VHSIC hardware description language, VHSIC stands for very high-speed integrated circuits program by the United States Department of Defense), or other suitable format. The CAD tool 206 analyzes the high level coding 202, or, equivalently, analyzes the design for the circuit as presented in the high level coding 202, in multiple processes, or an integrated process, and generates various forms of information that guide further development and implementation of the design. These various forms of information are presented as output to a user and/or are used internally in the system for automated design development and implementation processes, in various embodiments.

One form of useful information is that the CAD tool 206 generates a routability estimation 106 for the design for the circuit, which informs the user and/or the system about the amount of routing that the design for the circuit is estimated to consume when implemented on an FPGA. One form of useful information is that the CAD tool 206 generates a logic usage estimation 218 for the design for the circuit, which informs the user and/or the system about the amount of logic that the design for the circuit is estimated to consume when implemented on an FPGA. The format and content of the routability estimation 106 and logic usage estimation 218 may be implementation specific, and could include counts, ratios, ranges and/or sizes of estimated routing generally or more specifically such as signal counts, bus sizes and counts, clock counts and routing, etc., and counts, ratios, ranges and/or sizes of estimated logic generally or more specifically such as logic gate counts overall or for various types of logic, etc.

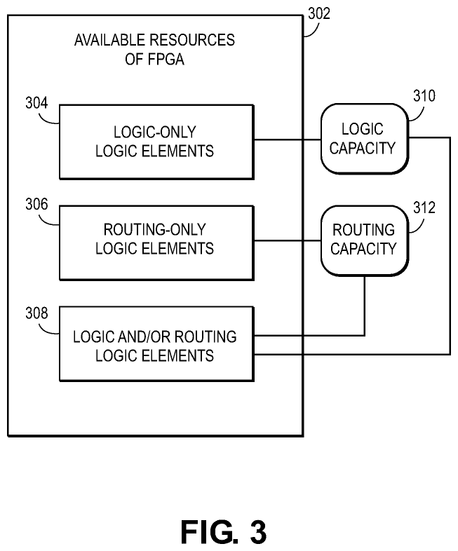

One form of useful information generated in some embodiments is that the CAD tool 206 generates an implementability determination 220, which informs the user and/or the system about whether or not the design for the circuit, as presented in the high level coding 202, is implementable on a specific FPGA. For example, the CAD system 204 could access information about one or more specific FPGAs, or the user could enter a selection for a specific FPGA that is intended for programming in the circuit that the user has entered in the high level coding 202. The CAD system 204 compares the routability estimation 106 and the logic usage estimation 218 for the design for the circuit to available resources of an FPGA (see FIG. 3), and determines whether the resources asked for in the routability estimation 106 and the logic usage estimation 218 fit within the available resources of such an FPGA. If so, the implementability determination 220 returns positive (indicating that the implementation is possible on the FPGA), and if not, negative (indicating that the implementation is not possible on the FPGA), optionally with the appropriate details such as shortfall in routability or shortfall in logic availability on the FPGA, or a ratio of resources asked for versus resources available in the FPGA, etc. Various formats for this information may be implementation specific and are readily devised. In one embodiment, upon a negative implementability determination 220, the CAD tool 206 automatically, or with user input, selects another specific FPGA, and retries the implementability determination 220. In one embodiment, upon a positive implementability determination 220, the CAD tool 206 automatically, or with user input, selects one or more other FPGAs, and retries the implementability determination 220 in order to see if a smaller or less expensive FPGA would suffice for the design for the circuit.

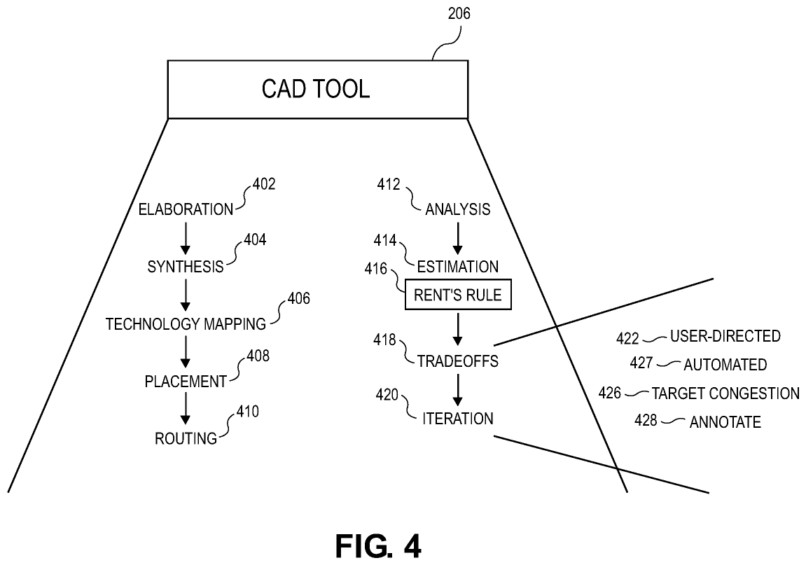

In some embodiments, the system awaits further input, and in other embodiments, the system proceeds automatically. For a positive implementability determination 220, in one embodiment the CAD system 204 generates FPGA-specific coding 212 of the design, e.g., design physical synthesis for a specific FPGA, for use in programming the FPGA. Further, the system may proceed and produce a programmed FPGA 214, for example by sending a bitstream to an FPGA that is mounted in a programming socket. Operation of a suitable embodiment of a CAD tool 206 is further described below with reference to FIG. 4.

FIG. 3 shows an embodiment of available resources 302 of an FPGA in an embodiment. The FPGA could have logic-only logic elements 304, routing-only logic elements 306, and versatile logic elements 308 that can be used for logic, routing, as one or the other in a trade off, or both in the same logic element. Other FPGAs may have the logic-only logic elements 304 and the routing-only logic elements 306, and not have the logic and/or routing logic elements 308. The format for how these various logic elements are represented internally for a CAD tool 206 may be implementation specific and are readily devised. Different specific FPGAs will have different amounts and possibly different types of logic elements, and may refer to such through other terminology while adhering to the principles described herein, for CAD tool analysis of available resources 302 of an FPGA.

In the embodiment shown in FIG. 3, the logic-only logic elements 304 and a variable, or possibly a minimum and a maximum value, of the amount of logic available in the logic and/or routing logic elements 308 is counted in the logic capacity 310 of a given FPGA. Likewise, the routing-only logic elements 306 and a variable, or possibly a minimum and a maximum value, of the amount of routing available in the logic and/or routing logic elements 308 is counted (i.e., accounted for, reckoned with) in the routing capacity 312 of a given FPGA.

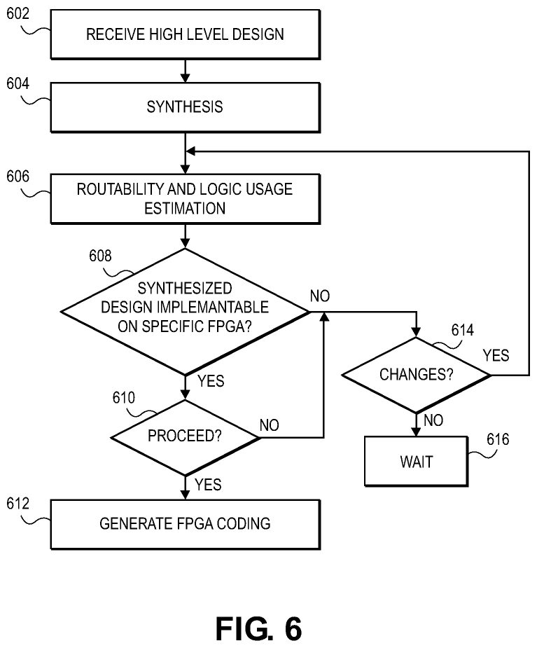

FIG. 4 shows aspects of a CAD tool 206 in an embodiment. This CAD tool 206 is based on both a standard flow for design implementation in a programmed FPGA, and features and capabilities described herein for fitting a design for a circuit into an FPGA, including analyzing for fit and optimizing through changes (see FIG. 6). The various features and capabilities are guided through user interaction and/or automation, in various embodiments.

On the left side in FIG. 4, the standard flow for the CAD tool 206 to proceed from high level coding 202 of the design for the circuit (see FIGS. 1 and 2) to the FPGA-specific coding 212 of the design, and further to the programmed FPGA 214, is elaboration 402, synthesis 404, and technology mapping 406, followed by placement 408 and routing 410. These processes are readily understood as terms of art with ready implementation in various CAD tools. It should be noted that the technology mapping 406 in both the standard flow and any modified flow applicable herein would be specific to the FPGA and in an appropriate format. For example, technology mapping 406 could be made to a netlist specific to an FPGA architecture.

On the right side in FIG. 4, the CAD tool 206 performs analysis 412 of the design, more specifically the high level coding 202 and inferences that can be drawn from the high level coding 202. The CAD tool 206 performs estimation 414, producing the routability estimation 106 and logic usage estimation 218 as shown in FIG. 2. In one embodiment, the estimation 414 is performed after synthesis 404 (e.g., logic synthesis), and before technology mapping 406, placement 408 and routing 410 (e.g., physical synthesis). The user, and the system itself, thus obtains useful information in the form of the routability estimation 106 and logic usage estimation 218, as well as the implementability determination 220, before the system consumes more time and computing power to perform the technology mapping 406, placement 408 and routing 410. A major benefit of this process and the timing and availability of this useful information is that the user or the CAD tool 206 can make decisions and changes, as appropriate, and in a much quicker and more timely manner than if the user or the system had to wait until the system was done with placement 408 and routing 410 for each cycle of iteration in a design process for implementation in an FPGA.

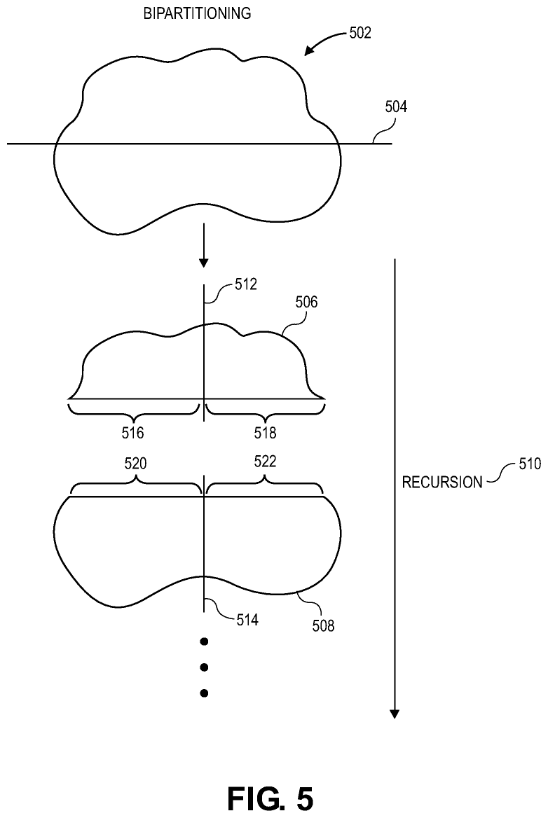

In one embodiment, estimation 414 is performed using Rent's rule 416, which relates the number of external signal connections to a logic block and the number of logic gates in a logic block, and which is well-known in the art. Various embodiments of the CAD tool 206 and related systems and methods could use Rent's rule itself, variations of Rent's rule, e.g. with additional parameters, or an equation based on Rent's rule. One embodiment uses Rent's parameter, logic density and pin density as inputs to an equation that is a variation of Rent's rule with additional parameters, tuned for types of circuits in FPGAs. For example, a systolic array that needs connection only among nearest neighbors has a connectivity that is largely serviced by the placement of the array members, and has relatively lower routability requirement. A crossbar design where every input has to be switched to every output is routing heavy and has a relatively higher routability requirement. Example Rent parameters may range from 0.5 (or a little bit lower) for a systolic array, to 0.7 or 0.75 for a crossbar design, inside of this range for many types of logic circuits, and outside of this range for unusual circuits. Rent's rule 416 is readily applied with a Rent parameter, and may be applied iteratively, recursively and/or hierarchically in various embodiments. For example, a hierarchical design can be developed by the system from the high level coding 202 of the design for the circuit, and the signal connections and logic gates determined at the various levels in the hierarchical design as the routability estimation 106 and logic usage estimation 218 are generated. In some embodiments, the system uses various forms of partitioning during analysis, such as bipartitioning as described below with reference to FIG. 5. Rent's rule and variations thereof can be applied with system recognition of various structures and associated numbers of pins (e.g., an adder, an array, a switch, registers, combinatorial logic, a clocked state machine, shifters, lookup tables, RAM, a DSP, etc.) at various levels in the hierarchy, and this in turn can guide partitioning and estimating.

Various embodiments of the CAD tool 206 perform estimation 414 (see FIG. 4) to generate routability estimation 106 and logic usage estimation 218, for the implementability determination 220 (see FIG. 2), through an algorithm and/or an equation that is based on or related to Rent's rule. Development of a suitable algorithm(s) or equation(s) that predicts routability of an architecture is part of a design process for development of various CAD tool 206 embodiments, and usage of such a suitable algorithm or equation by the CAD tool 206 and CAD system 204 is part of usage by a user of the CAD tool 206 and CAD system 204. A suitable algorithm or equation can be general to integrated circuits, general to programmable devices, specific to FPGAs in general, or specific to one or more specific FPGA architectures, in various embodiments. Different algorithms or equations may be suitable for different FPGA architectures. Parameters in the various algorithms or equations can be set or tuned, for example through predictive or empirically gathered statistics applicable to the general or specific architecture(s), in various embodiments.

For an example equation that is based on Rent's rule and suitable in an embodiment of CAD tool 206, the system could define utilization as follows:

$$utilization = {logic\_elements}^{*} ( 1 + max ( 0 , ( {pin\_density}^{*} rent\_parameter ) - normalizer ) )$$

where normalizer is a parameter that would be equal pin_density*rent_parameter when those values are low enough that you can use 100% of all logic elements for logic and not routing. Variations and algorithmic usage of this example equation, including versions with further parameters, versions operating at multiple levels of an FPGA design, and versions for multiple FPGA architectures, are readily developed in keeping with the teachings herein.

In various embodiments, the system performs trade-offs 418 and iteration 420. Trade-offs 418 and iteration 420 can be automated 424 and/or user-directed 422. In one embodiment, the system can target congestion 426. In various embodiments, the system can annotate 428 the design, in an appropriate format. Take for example logic duplication. Logic duplication is done to improve delay, so that chokepoints in the graph of a circuit are minimized by duplicating nodes where the chokepoint is found. Signals going through a chokepoint are split into two, which improves performance in terms of speed but also increases area. This is a trade-off and an option that synthesis can explore to optimize. For example, there could be trade-offs 418 in speed versus area on a global basis, a local basis, a hierarchical basis in the design, etc., and these can be automated or guided through user interaction, in various embodiments. A trade-off 418 in speed versus area on a global basis could be implemented through user or system selection to emphasize speed for the entire FPGA, or emphasize minimizing area for a circuit implementation on the FPGA. A trade-off 418 in speed versus area on a local basis could be implemented through user or system selection of specific portion(s) of the design, in which emphasize speed, or minimize area. A trade-off 418 in speed versus area on a hierarchical basis could be implemented through user or system selection in a hierarchical design of a specific level of the hierarchy, or portion of a design at a specific level in the hierarchy, in which to emphasize speed, or minimize area. The system could annotate 428 a design database 210 (see FIG. 2), with results of chokepoint determination or other targeted congestion, such as a logic section with a large amount of routing, or a large amount of speed-critical routing. The system could indicate candidates for trade-offs 418 between speed and area, through a user interface and/or annotation. In some embodiments, the annotated design database 210 is visible through a user interface, so that the user can read annotation, understand the context of the annotation in the design database 210, and issue instructions to the system for trade-offs Then, the system could iterate changes and estimation, or the user could specify changes based on viewing or being alerted to the annotation. For example, the system could apply speed mode or area mode, through trade-offs 418 and iteration 420.

As an example of how this could work at various levels in a design, the CAD tool 206 could analyze various costs inside of optimization algorithms. A cost for minimizing wire(s), a cost for minimizing critical path delay, and a relative weighting of wire cost versus critical path cost, could each be applied during analysis 412 and trade-offs 418 at each level in a hierarchical design (or for that matter, a flat design).

As a further example of how this could work in a hierarchical design, consider a design at top level, then a lower level has a DDR (double data rate) interface, and another level has an ALU (arithmetic logic unit). The system can analyze how many logic elements are being used for the DDR interface, how many for the ALU, how is routing done for each of these, and so on. The system could provide a synthesis option for a specific module, or respond to automated or user direction to work harder on increasing routing efficiency, speed or decreasing area for the module. In some versions, the system could annotate 428 the design, for example in a database 210 (see FIGS. 2 and 4) with findings or options for trade-offs 418. And again, this could be applied at various levels in a hierarchical design.

FIG. 5 shows bipartitioning, with recursion, as a featured capability of a CAD tool in an embodiment. This is a conceptual diagram, readily applied in making and using a CAD tool 206, as follows. Contents of a design 502 are subjected to a partition 504 that divides the design 502 into a first design portion 506 and a second design portion 508. Signals crossing the boundaries of the first design portion 506 and second design portion 508 can be analyzed, as can the amount of logic within each. Applying recursion 510, each of these design portions 506, 508 is subjected to another partition 512, 514, further dividing the design into a third portion 516, a fourth portion 518, a fifth portion 520 and a sixth portion 522. Again, signals crossing boundaries, and amount of logic within each design portion, can be analyzed. In some embodiments, the partitioning is adjusted and recalculations are made, results yielding lesser amounts of routing are selected automatically as optimizing routing. Recursion 510 can stop there, or continue, in various embodiments. In some embodiments, the recursion 510 is stopped when routability estimation 106 and logic usage estimation 218 converge in comparison to previous iterations, for example to within a threshold.

FIG. 6 is a flow diagram of a method that is practiced by a CAD system, in an embodiment. More specifically, the method is practiced by a processor, for example by software executing on the processor, firmware, hardware, or various combinations thereof, in a CAD system. Instructions for a processor to practice the method can be embodied in tangible, non-transient, computer-readable media.

In an action 602, the system receives a high level design. The high level design is a design for a circuit to be implemented in an FPGA, and is represented in an appropriate high level coding.

In an action 604, the system performs synthesis. Synthesis (e.g., logic synthesis) results in a synthesized design, in an appropriate format for the CAD system. At this point in the method, the synthesized design is independent of any specific FPGA, for example the synthesized design has not yet been technology mapped.

In an action 606, the system performs routability and logic usage estimation. Various techniques, parameters, and specifics for FPGAs, are discussed above as applicable for various embodiments performing estimation.

In a determination action 608, the system determines whether the synthesized design is implementable on a specific FPGA. For example, the routability and logic usage estimation can be compared to available resources of the FPGA on an absolute, relative or ratio basis, etc., for such a determination. If the result is yes, the synthesized design is implementable on a specific FPGA, flow proceeds to the determination action 610. If the answer is no, the synthesized design is not implementable on a specific a PGA, flow proceeds to the determination action 614.

In the determination action 610, it is determined whether to proceed. If the answer is no, do not proceed, flow branches to the determination action 614. If the answer is yes, do proceed, flow proceeds to the action 612, to generate FPGA coding. FPGA coding could be in the FPGA-specific coding 212 of the design as shown in FIG. 2, as used for producing the programmed FPGA 214.

In the determination action 614, it is determined whether there are any changes. If no, there are no changes, the system goes to wait 616 (e.g., wait for additional instructions), or optionally exits from the flow. If yes, there are changes, flow proceeds back to the action 606 to again perform the routability and logic usage estimation. For example, changes could be automated, or through user interaction, or a combination of both. Changes could be guided by some of the factors discussed in FIG. 4.

Thus, one goal of some embodiments described herein, and a specific usage of an embodiment, is to determine whether or not a design for a circuit fits available resources of a specific FPGA. One goal of some embodiments described herein is to successfully generate FPGA coding, for a design for a circuit that it is determined fits the available resources of a specific FPGA. One goal of some embodiments described herein is to provide useful information as feedback to the system and the user, during the design flow for a design to be implemented on an FPGA.

In various embodiments of a method, a CAD tool, and a CAD system, various indications of targeting congestion, trade-offs, system determinations, user interaction with a CAD tool, the design and implementation of the design in an FPGA are presented to a user through a user interface. Specific aspects of such a user interface are readily devised and may be specific to a FPGA product line or product family, a manufacturer of FPGAs, a design flow, or a design of a CAD tool or CAD system.

Some portions of the detailed descriptions above are presented in terms of algorithms and symbolic representations of operations on data bits within a computer memory. These algorithmic descriptions and representations are the means used by those skilled in the data processing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the following discussion, it is appreciated that throughout the description, discussions utilizing terms such as “processing” or “computing” or “calculating” or “determining” or “displaying” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

The present invention also relates to apparatus for performing the operations herein. This apparatus may be specially constructed for the required purposes, or it may comprise a general-purpose computer selectively activated or reconfigured by a computer program stored in the computer. Such a computer program may be stored in a computer readable storage medium, such as, but is not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, and each coupled to a computer system bus.

The algorithms and displays presented herein are not inherently related to any particular computer or other apparatus. Various general-purpose systems may be used with programs in accordance with the teachings herein, or it may prove convenient to construct more specialized apparatus to perform the required method steps. The required structure for a variety of these systems will appear from the description below. In addition, the present invention is not described with reference to any particular programming language. It will be appreciated that a variety of programming languages may be used to implement the teachings of the invention as described herein.

A machine-readable medium includes any mechanism for storing or transmitting information in a form readable by a machine (e.g., a computer). For example, a machine-readable medium includes read only memory (“ROM”); random access memory (“RAM”); magnetic disk storage media; optical storage media; flash memory devices; electrical, optical, acoustical or other form of propagated signals (e.g., carrier waves, infrared signals, digital signals, etc.); etc.

Whereas many alterations and modifications of the present invention will no doubt become apparent to a person of ordinary skill in the art after having read the foregoing description, it is to be understood that any particular embodiment shown and described by way of illustration is in no way intended to be considered limiting. Therefore, references to details of various embodiments are not intended to limit the scope of the claims which in themselves recite only those features regarded as essential to the invention.

What is claimed is:

1. A method, performed by a computer aided design (CAD) system, comprising:
receiving a high level coding of a design for a circuit to be implemented in a field programmable gate array (FPGA);
performing synthesis on the design, to produce a synthesized design;
generating a routability estimation and a logic usage estimation for the synthesized design; and
determining whether the synthesized design is implementable on a specific FPGA, based on the routability estimation, the logic usage estimation, and available resources of the specific FPGA.

2. The method performed by the CAD system of claim 1, wherein:
the available resources of the specific FPGA comprise logic capacity and routing capacity; and
the determining comprises comparing the logic usage estimation and the logic capacity, and comparing the routability estimation and the routing capacity.

3. The method performed by the CAD system of claim 1, wherein:
the available resources of the specific FPGA comprise first logic elements (LEs) that are logic-only, second logic elements that are routing-only, and third logic elements that are usable for either of logic and routing; and
the determining comprises determining whether the logic usage estimation and the routability estimation fit within the combined first, second and third logic elements including a trade-off in usage of the logic and the routing of the third logic elements.

4. The method performed by the CAD system of claim 1, wherein:
the generating the routability estimation and the logic usage estimation are in accordance with Rent's rule regarding a relationship between a number of external signal connections to a logic block and a number of logic gates in the logic block; and
the generating includes recursive bipartitioning of the synthesized design.

5. The method performed by the CAD system of claim 1, further comprising:
trading off speed and area on a per block, per group of blocks, hierarchical, or global basis; and
repeating the determining after at least one such trade-off.

6. The method performed by the CAD system of claim 1, further comprising:
targeting congestion in the synthesized design; and
repeating the determining, after a change to a targeted congestion.

7. The method performed by the CAD system of claim 1, further comprising:
annotating a design database with synthesis directives to reduce logic used, reduce connectivity, trade-off speed and area, or reduce congestion, responsive to determining the synthesized design is not implementable on the specific FPGA.

8. A tangible, non-transitory, computer-readable media having instructions thereupon which, when executed by a processor, cause the processor to perform a method comprising:
receiving a high level coding of a design for a circuit to be implemented in a field programmable gate array (FPGA);
performing synthesis on the design, to produce a synthesized design;
generating a routability estimation and a logic usage estimation for the synthesized design; and
determining and indicating to a user whether the synthesized design is implementable on a specific FPGA, based on the routability estimation, the logic usage estimation, and available resources of the specific FPGA.

9. The computer-readable media of claim 8 wherein:
the available resources of the specific FPGA comprise logic capacity and routing capacity;
the determining comprises comparing the logic usage estimation and the logic capacity, and comparing the routability estimation and the routing capacity; and
the indicating to the user comprises a user interface.

10. The computer-readable media of claim 8 wherein:
the available resources of the specific FPGA comprise first logic elements (LEs) that are logic-only, second logic elements that are routing-only, and third logic elements that are usable for either of logic and routing; and
the determining comprises determining whether the logic usage estimation and the routability estimation fit within the combined first, second and third logic elements including a trade-off in usage of the logic and the routing of the third logic elements.

11. The computer-readable media of claim 8 wherein:
the generating the routability estimation and the logic usage estimation are in accordance with Rent's rule regarding a relationship between a number of external signal connections to a logic block and a number of logic gates in the logic block; and
the generating includes recursive bipartitioning of the synthesized design.

12. The computer-readable media of claim 8, wherein the method further comprises:
indicating to a user regarding trading off speed and area on a per block, per group of blocks, hierarchical, or global basis; and
repeating the determining after at least one such trade-off.

13. The computer-readable media of claim 8, wherein the method further comprises:
indicating to a user regarding targeting congestion in the synthesized design; and
repeating the determining, after a change to a targeted congestion.

14. The computer-readable media of claim 8, wherein the method further comprises:
indicating to a user regarding annotating a design database with synthesis directives to reduce logic used, reduce connectivity, trade-off speed and area, or reduce congestion, responsive to determining the synthesized design is not implementable on the specific FPGA.

15. A computer aided design (CAD) system, comprising:
a memory, to receive a high level coding of a design for a circuit to be implemented in a field programmable gate array (FPGA); and
a processor, to:
perform synthesis on the design, to produce a synthesized design;
generate a routability estimation and a logic usage estimation for the synthesized design; and
determine whether the synthesized design is implementable on a specific FPGA, based on the routability estimation, the logic usage estimation, and available resources of the specific FPGA.

16. The CAD system of claim 15, wherein:
the available resources of the specific FPGA comprise logic capacity and routing capacity; and
to determine comprises comparing the logic usage estimation and the logic capacity, and comparing the routability estimation and the routing capacity.

17. The CAD system of claim 15, wherein:
the available resources of the specific FPGA comprise first logic elements (LEs) that are logic-only, second logic elements that are routing-only, and third logic elements that are usable for either of logic and routing; and
to determine comprises determining whether the logic usage estimation and the routability estimation fit within the combined first, second and third logic elements including a trade-off in usage of the logic and the routing of the third logic elements.

18. The CAD system of claim 15, wherein:
to generate the routability estimation and the logic usage estimation is according to Rent's rule regarding a relationship between a number of external signal connections to a logic block and a number of logic gates in the logic block; and
to generate includes recursive bipartitioning of the synthesized design.

19. The CAD system of claim 15, further comprising the processor to:
target congestion in the synthesized design;
trade off speed and area on a per block, per group of blocks, hierarchical, or global basis; and
repeat such determining, after a change to a targeted congestion.

20. The CAD system of claim 15, further comprising the processor to:
annotate a design database with synthesis directives to reduce logic used, reduce connectivity, trade-off speed and area, or reduce congestion, responsive to determining the synthesized design is not implementable on the specific FPGA.
